(19) United States
(12) Patent Application Publication
(10) Pub. No.: US 2008/0169522 A1
(43) Pub. Date: Jul. 17, 2008

(54) MOVING ELEMENT AND METHOD OF MANUFACTURING THE SAME

(75) Inventor: Michitsugu ARIMA, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/014,428

(22) Filed: Jan. 15, 2008

(30) Foreign Application Priority Data
Jan. 17, 2007 (JP) 2007-008143
Nov. 7, 2007 (JP) 2007-290045

(51) Int. Cl. H01L 29/84; H01L 21/306

(52) U.S. Cl. 257/415; 438/50; 257/E21.219

(57) ABSTRACT

A moving element includes at least a substrate including a support, a moving body, and an elastic body connecting the moving body to the support. The support includes a buried film formed in it. The buried film of the support is formed only near end faces of the support that faces the moving body.

### CROSS-REFERENCE TO RELATED APPLICATIONS

This application is based upon and claims the benefit of priority from prior Japanese Patent Applications No. 2007-008143, filed Jan. 17, 2007; and No. 2007-290045, filed Nov. 7, 2007, the entire contents of both of which are incorporated herein by reference.

### BACKGROUND OF THE INVENTION

1. Field of the Invention

The present invention relates to a moving element manufactured by processing a substrate and a method of manufacturing the same and, more particularly, to a MEMS (Micro Electro Mechanical System) element manufactured by processing an SOI (Silicon on Insulator) substrate and a method of manufacturing the same.

2. Description of the Related Art

A MEMS element is one type of micromachine element, and is intensively studied recent years because a high-function micromachine element can be efficiently manufactured at a low cost by employing a method of manufacturing a semiconductor device such as an LSI (Large Scale Integration) element.

An example of the MEMS element includes a group of those which are so-called bulk micromachines formed by processing a substrate such as a silicon substrate to form some of constituent elements. A method that uses an SOI (Silicon on Insulator) substrate has been conventionally used as a method of manufacturing such a bulk micromachine. This method is employed for various types of MEMS elements. US2003/0169962 discloses a light-control tilt mirror element as an example of such a MEMS element.

### BRIEF SUMMARY OF THE INVENTION

A moving element according to the present invention comprises at least a substrate including a support, a moving body, and an elastic body connecting the moving body to the support. The support includes a buried film formed in it. The buried film of the support is formed only near end faces of the support that face the moving body.

A method of manufacturing a moving element according to the present invention comprises steps of preparing a substrate in which a patterned buried film is buried, forming a first etching mask on a first surface of the substrate and forming a second etching mask on a second surface located on a rear side of the first surface, etching, from the first surface, only a portion of the substrate that is not covered with the first etching mask until the buried film is exposed, etching, from the second surface, only a portion of the substrate that is not covered with the second etching mask until the buried film is exposed, and removing a portion of the buried film that is exposed to an outside.

Another method of manufacturing a moving element according to the present invention comprises steps of preparing a substrate in which a patterned buried film is buried, forming a first etching mask on a first surface of the substrate and forming an etching stop film on a second surface located on a rear side of the first surface, etching, from the first surface, only a portion of the substrate that is not covered with the first etching mask until the buried film is exposed, removing part of an exposed portion of the buried film to form a second etching mask, and etching, from the first surface, only a portion of the substrate that is not covered with the second etching mask until the etching stop film is exposed.

Still another method of manufacturing a moving element according to the present invention comprises steps of preparing a substrate in which a patterned buried film is buried, forming an etching mask on a first surface of the substrate and forming an etching stop film on a second surface located on a rear side of the first surface, etching, from the first surface, only a portion of the substrate that is not covered with the etching mask until the buried film is exposed, and subsequently, etching only a portion of the substrate which is not covered with the buried film until the etching stop film is exposed.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a tilt mirror element according to the first embodiment of the present invention;

FIG. 2 is a sectional view of the tilt mirror element taken along the line A-B in FIG. 1;

FIGS. 3 to 9 sequentially show steps in a method of manufacturing the tilt mirror element shown in FIGS. 1 and 2;

FIG. 10 shows in enlargement the bonding portion shown in FIG. 6;

FIG. 11 shows how an active layer is partly undesirably etched due to etching mask misalignment when a thermal oxide film pattern has the same size as that of an active region;

FIG. 12 shows how an active layer is partly undesirably etched as it is etched in the planar direction of a substrate when a thermal oxide film pattern has the same size as that of an active region;

FIG. 13 is a sectional view, corresponding to FIG. 6, of a structure in which a mesh-like oxide film pattern is formed simultaneously with a thermal oxide film pattern in the step in FIG. 5;

FIG. 14 is a plan view of the thermal oxide film pattern and mesh-like oxide film pattern shown in FIG. 13;

FIG. 15 shows another oxide film pattern that is an alternative to the grid-like oxide film pattern shown in FIG. 14;

FIG. 16 shows still another oxide film pattern that is an alternative to the grid-like oxide film pattern shown in FIG. 14;

FIG. 17 is a perspective view of a tilt mirror element according to the second embodiment of the present invention;

FIG. 18 is a sectional view of the tilt mirror element taken along the line C-D in FIG. 17;

FIGS. 19 to 21 sequentially show steps in a method of manufacturing the tilt mirror element shown in FIGS. 17 and 18;

FIGS. 22 to 24 sequentially show steps of fabricating the substrate shown in FIG. 19;

FIG. 25 is a sectional view taken along the line E-F in the step of FIG. 21;

FIG. 26 is a perspective view of a tilt mirror element according to a modification of the second embodiment;

FIG. 27 is a sectional view of the tilt mirror element taken along the line G-H in FIG. 26;

FIG. 28 shows the initial step in the manufacture of the tilt mirror element shown in FIGS. 26 and 27;

FIG. 29 is a perspective view of a tilt mirror element comprising a single substrate;

FIG. 30 is a sectional view of the tilt mirror element taken along the line I-J in FIG. 29;

FIG. 31 is a perspective view of a tilt mirror element according to the third embodiment of the present invention;

FIG. 32 is a sectional view of the tilt mirror element taken along the line K-L in FIG. 31;

FIGS. 33 to 35 sequentially show steps in a method of manufacturing the tilt mirror element shown in FIGS. 31 and 32;

FIGS. 36 to 39 sequentially show steps in another method of manufacturing the tilt mirror element shown in FIGS. 31 and 32;

FIGS. 40 to 42 sequentially show steps in another method of manufacturing the tilt mirror element shown in FIGS. 17 and 18;

FIG. 43 is a perspective view of a conventional tilt mirror element;

FIG. 44 is a sectional view of the tilt mirror element taken along the line M-N in FIG. 43;

FIGS. 45 to 50 sequentially show steps in a method of manufacturing the tilt mirror element shown in FIGS. 43 and 44;

FIG. 51 shows a tilt mirror element array formed by arranging tilt mirror elements each shown in FIGS. 43 and 44 vertically and horizontally in an array; and

FIG. 52 shows how a mirror substrate floats from an MCM substrate due to the warp of a mirror support outer frame.

### DETAILED DESCRIPTION OF THE INVENTION

Prior to the description of the embodiments of the present invention, a tilt mirror element that is substantially similar to the tilt mirror element disclosed in US2003/0169962 will be described with reference to the drawing.

FIGS. 43 and 44 show this tilt mirror element. This tilt mirror element 1100 comprises a mirror substrate 1110 and an MCM (Multi Chip Module) substrate 1130. The mirror substrate 1110 comprises a mirror support outer frame 1111, torsion springs 1112 and 1114, a mirror support inner frame 1113, and a mirror plate 1115. The mirror plate 1115 is connected to the mirror support inner frame 1113 by the torsion springs 1114, and the mirror support inner frame 1113 is connected to the mirror support outer frame 1111 by the torsion springs 1112. The mirror substrate 1110 and MCM substrate 1130 are bonded to each other through pads 1150. The MCM substrate 1130 has two electrodes 1131 at positions opposing the mirror support inner frame 1113, and two electrodes 1132 at positions opposing the mirror plate 1115.

As shown in FIG. 44, the mirror support outer frame 1111 comprises silicon oxide films 1122, 1123, and 1125, and silicon layers 1121 and 1124.

To drive this tilt mirror element 1100, while the mirror plate 1115 and mirror support inner frame 1113 are grounded, a voltage is applied to, of the electrodes 1131 and 1132, only one electrode 1131 located on one side of the torsion springs 1112, and only one electrode 1132 located on one side of the torsion springs 1114. As a result, an electrostatic attracting force is generated among the electrodes 1131 and 1132, mirror plate 1115, and mirror support inner frame 1113. One side of the mirror plate 1115 or one side of mirror support inner frame 1113 is attracted to the electrode 1131 and 1132 by the electrostatic attracting force, so that the mirror plate 1115 is deflected in a desired direction.

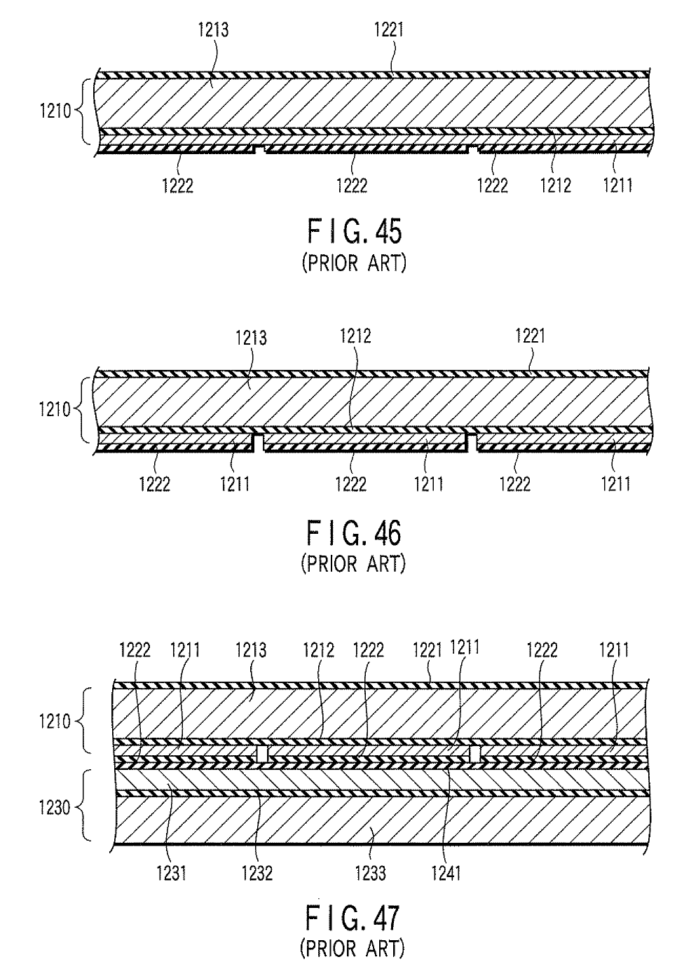

FIGS. 45 to 50 sequentially show steps in a method of manufacturing the tilt mirror element shown in FIGS. 43 and 44. As shown in FIG. 45, an SOI substrate 1210, comprising an active layer 1211, a BOX (Buried Oxide) layer 1212, and a support layer 1213, is prepared, thermal oxide films 1221 are formed on the upper and lower surfaces of the SOI substrate 1210, and the thermal oxide film 1221 formed on the active layer side is patterned to form a first etching mask 1222.

As shown in FIG. 46, the portion of the active layer 1211 that is not covered with the etching mask 1222 is etched until the BOX layer 1212 is exposed. The BOX layer 1212 serves as an etching stop layer.

As shown in FIG. 47, another SOI substrate 1230, comprising an active layer 1231, a BOX layer 1232, and a support layer 1233, is prepared, a thermal oxide film 1241 is formed on the active layer 1231 of the SOI substrate 1230, and the structure fabricated in FIG. 46 is bonded to the resultant SOI substrate 1230.

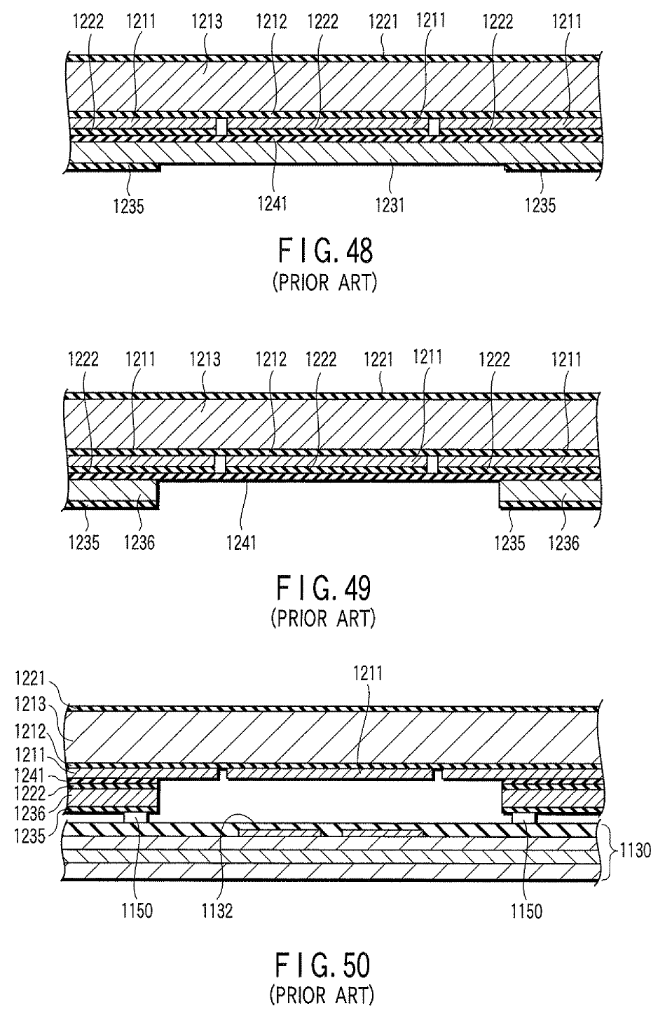

The support layer 1233 is removed, and the exposed BOX layer 1232 is patterned to form a second etching mask 1235, as shown in FIG. 48.

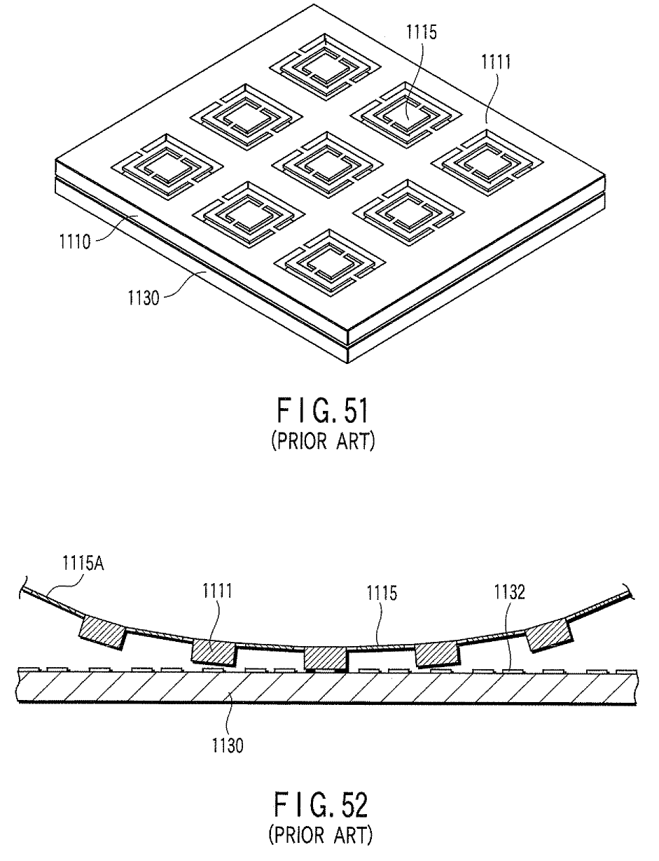

As shown in FIG. 49, the portion of the active layer 1231 that is not covered with the second etching mask 1235 is etched until the thermal oxide film 1241 is exposed. The thermal oxide film 1241 serves as an etching stop layer. The exposed portion of the thermal oxide film 1241 is removed, and the resultant structure is bonded to the MCM substrate 1130 formed with the electrodes 1132 and pads 1150, as shown in FIG. 50. Finally, the thermal oxide film 1221, support layer 1213, and BOX layer 1212 are removed, thus completing the tilt mirror element 1100 shown in FIGS. 43 and 44.

As shown in FIGS. 45 to 50, the method of manufacturing the MEMS element using the SOI element uses the BOX layer made of silicon oxide as the etching stop layer when forming an Si multistage structure by etching. This provides various advantages, i.e., the etching depth of the Si substrate is controlled accurately, and the bottom surface of the etching opening is finished smoothly. In particular, as the etching depth is directly reflected in the sizes of the respective members that constitute the element, the etching depth control is very important.

For example, when etching the active layer 1211 in the step of FIG. 46, if a normal substrate with no BOX layer 1212 is used, etching must be interrupted and the etching depth must be measured. An etching rate and a time necessary for etching to a target depth must be calculated from the measurement value of the etching depth and the time required for etching until the measurement. Then, etching must be performed again. A complicated procedure is thus necessary. As the etching rate usually differs among positions on the location of the substrate, it is difficult for this method to accurately control the etching depth of the entire substrate.

The manufacturing method using the SOI substrate in this manner has many advantages in terms of step design. On the other hand, as shown in FIG. 44, the silicon oxide films 1122, 1123, and 1125 buried in the substrate remain as element constituent elements. Then, the stress remaining in the interface between the silicon layer 1121 and silicon oxide film 1122 and between the silicon layer 1124 and silicon oxide films 1123 and 1125 warps the mirror support outer frame 1111 undesirably. This problem adversely, greatly affects particularly the performance of a large chip used in, e.g., an optical switch for light communication. An example of the adverse influence will be described with reference to FIGS. 51 and 52.

FIG. 51 shows a chip formed by arranging tilt mirror elements each shown in FIGS. 43 and 44 vertically and horizontally in an array. When such a chip is fabricated by the method shown in FIGS. 45 to 50, a stress remaining in an interface between a silicon oxide film and a silicon layer in a mirror support outer frame 1111 undesirably warps a mirror substrate 1110. Then, when bonding the mirror substrate 1110 to an MCM substrate 1130, as shown in FIG. 52, the mirror substrate 1110 floats from the MCM substrate 1130 at the end of the chip, and the gap between electrodes 1131 and 1132 and a mirror plate 1115 differs between the center and the end of the chip.

The driving efficiency of the tilt mirror element is inversely proportional to the square of the gap between the electrodes 1131 and 1132 and the mirror plate 1115. Accordingly, in FIG. 52, at a position close to the end of the chip, the mirror plate is difficult to drive. If the mirror support outer frame 1111 has a small thickness to avoid this difficulty in driving, the movable range of the mirror plate 1115 decreases near the center of the chip.

Furthermore, since, at the end of the chip, the mirror plate 1115 in a non-driving state is undesirably tilted, the driving efficiency and movable range change depending on the tilting direction of the mirror plate 1115. For example, a mirror plate 1115A in FIG. 52 is tilted clockwise. In this case, when comparing the case of tilting to the right and the case of tilting to the left, although the driving efficiency is high in the former case, the movable range decreases.

This problem can be reduced if the mirror substrate 1110 is bonded to the MCM substrate 1130 while applying a heavy load to the mirror substrate 1110 to correct its warp. In this case, however, the elastic reaction force of the mirror substrate 1110 constantly acts on the bonding portion. When the resultant tilt mirror element is used over a long period of time, the bonded substrate may be separated and the warp may appear again. This causes a problem in long-term reliability.

The embodiments of the present invention will be described with the drawing.

### First Embodiment

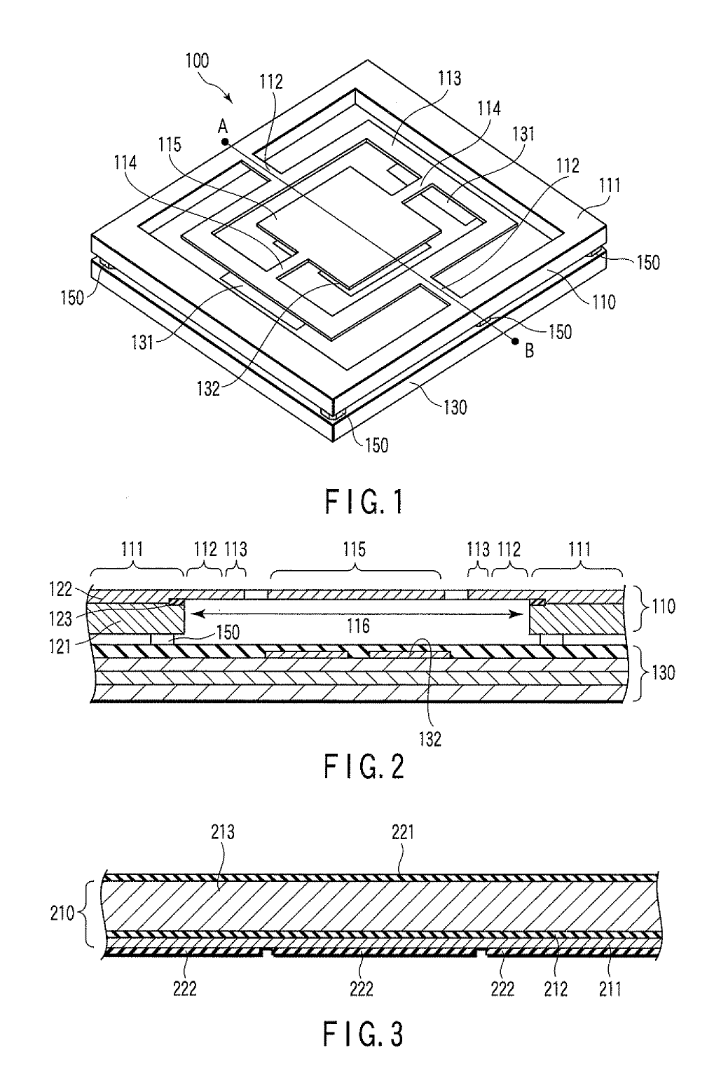

FIGS. 1 and 2 show a tilt mirror element as a moving element according to the first embodiment. The tilt mirror element 100 comprises a mirror substrate 110 and an MCM substrate 130. The mirror substrate 110 and MCM substrate 130 are bonded to each other through pads 150. The mirror substrate 110 comprises a mirror support outer frame 111, a mirror support inner frame 113 located inside the mirror support outer frame 111, two torsion springs 112 connecting the mirror support outer frame 111 to the mirror support inner frame 113, a mirror plate 115 located inside the mirror support inner frame 113, and two torsion springs 114 connecting the mirror support inner frame 113 to the mirror plate 115. The two torsion springs 112 are symmetrically arranged on a straight line extending through the center of the mirror support inner frame 113. Similarly, the two torsion springs 114 are symmetrically arranged on a straight line extending through the center of the mirror plate 115. The torsion springs 112 and torsion springs 114 extend perpendicularly to each other.

The MCM substrate 130 has two electrodes 131 opposing the mirror support inner frame 113, and two electrodes 132 opposing the mirror plate 115. The two electrodes 131 are axi-symmetrically arranged with respect to a straight line extending through the torsion springs 112. The two electrodes 132 are arranged axi-symmetrically with respect to a straight line extending through the torsion springs 114.

The torsion springs 112 are elastic and torsionally deformable. Thus, the mirror support inner frame 113 is allowed to tilt with respect to the mirror support outer frame 111. Similarly, the torsion springs 114 are elastic and torsionally deformable. Thus, the mirror plate 115 is allowed to tilt with respect to the mirror support inner frame 113. As the torsion springs 112 and 114 are perpendicular, the mirror plate 115 is allowed to tilt two-dimensionally. In the tilting operation of the mirror support inner frame with respect to the mirror support outer frame 111, the mirror support outer frame 111 serves as a support and the mirror support inner frame 113 serves as a moving body. In the tilting operation of the mirror plate 115 with respect to the mirror support inner frame 113, the mirror support inner frame 113 serves as a support and the mirror plate 115 serves as a moving body.

The tilt mirror element 100 is driven in the following manner. The mirror plate 115 and mirror support inner frame 113 are grounded. For example, when applying a voltage to one of the two electrodes 131, an electrostatic attracting force is generated between the voltage-applied electrode 131 and the mirror support inner frame 113. The voltage-applied electrode 131 attracts the mirror support inner frame 113 to tilt the mirror plate 115 about an axis extending through the torsion springs 112. When applying a voltage to one of the two electrodes 132, an electrostatic attracting force is generated between the voltage-applied electrode 132 and the mirror plate 115. The voltage-applied electrode 132 attracts the mirror plate 115 to tilt the mirror plate 115 about an axis extending through the torsion springs 114.

As shown in FIG. 2, the mirror support outer frame 111, torsion springs 112, mirror support inner frame 113, torsion springs 114, and mirror plate 115 comprise a silicon layer 122, and the mirror support outer frame 111 comprises two silicon layers, i.e., a silicon layer 121 and the silicon layer 122, and a silicon oxide film 123. The silicon layers 121 and 122 are preferably made of single-crystal silicon. The silicon oxide film 123 to be used for substrate processing is buried in the mirror support outer frame 111. The silicon oxide film 123 is formed only near an opening 116 of the mirror support outer frame 111 and does not exist elsewhere. Namely, the silicon oxide film 123 as the buried film is formed only near end faces of the mirror support outer frame 111 that face the mirror plate 115.

Consequently, in the prior art, the silicon oxide films 1122 and 1123 sandwiched by the two silicon layers 1121 and 1124 exist on the entire substrate surface as shown in FIG. 44, whereas in this embodiment, the area of the silicon oxide film 123 buried in the mirror support outer frame 111 is very small, as shown in FIG. 2. This largely decreases the warp of the mirror substrate 110 resulting from a difference in stress between silicon and silicon oxide.

A method of manufacturing the tilt mirror element shown in FIGS. 1 and 2 will be described with reference to FIGS. 3 to 16. In this description, the portion corresponding to the opening 116 of the mirror support outer frame 111 will be referred to as an active region. FIGS. 3 to 13 show sections corresponding to that in FIG. 2.

First, as shown in FIG. 3, an SOI substrate 210 comprising an active layer 211, a BOX (Buried Oxide) layer 212, and a support layer 213 is prepared. Thermal oxide films 221 are respectively formed on the upper and lower surfaces of the SOI substrate 210. The thermal oxide film 221 formed on the active layer 211 side is patterned to form a first etching mask 222. The first etching mask 222 has a pattern corresponding to the shape of the mirror support outer frame 111, torsion springs 112, mirror support inner frame 113, torsion springs 114, and mirror plate 115.

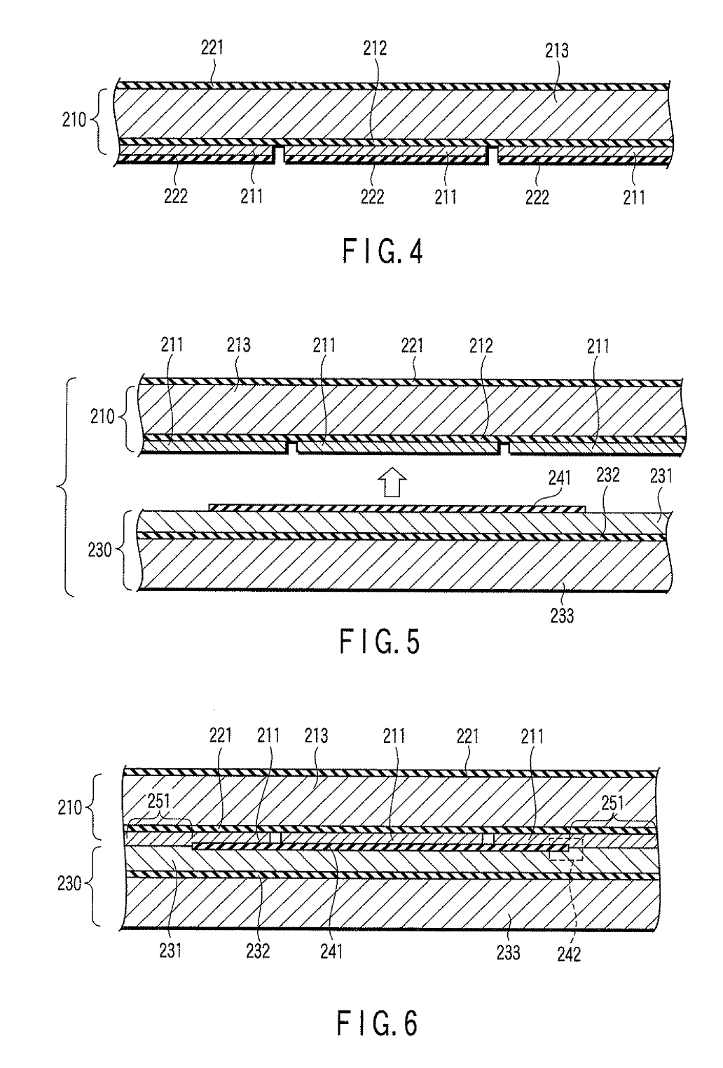

As shown in FIG. 4, the portion of the active layer 211 that is not covered with the etching mask 222 is etched until the BOX layer 212 is exposed. The BOX layer 212 serves as an etching stop layer.

Subsequently, as shown in FIG. 5, another SOI substrate 230 comprising an active layer 231, a BOX layer 232, and a support layer 233 is prepared. A thermal oxide layer is formed on the upper surface of the active layer 231 of the SOI substrate 230, and patterned to form a thermal oxide film pattern 241 only on the active region and its nearby region. The size of the thermal oxide film pattern 241 must be slightly larger than that of the active region considering the performance of an apparatus employed in the process. The reason for this will be described later in detail. Furthermore, the substrate fabricated in FIG. 4 is bonded to the upper surface of the thermal oxide film pattern 241 to obtain the structure shown in FIG. 6.

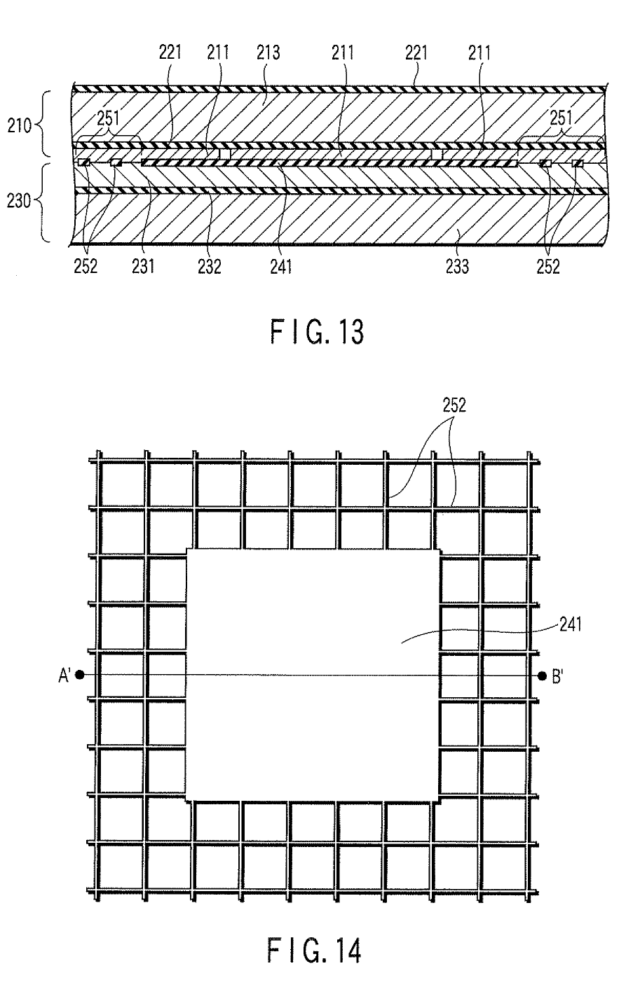

If the portion 251 of the thermal oxide film pattern 241 where the oxide film does not exist has a large area, in bonding the SOI substrate 210 to the SOT substrate 230 in FIG. 6, voids may be formed in the bonding interface oftener. To avoid this phenomenon, in the bonding interface of the SOI substrates 210 and 230, a mesh-like oxide film pattern 252 is added to the portion where the oxide film does not exist, as shown in FIGS. 13 and 14. FIG. 13 is a sectional view of a structure obtained when forming the mesh-like oxide film pattern 252 in accordance with the step shown in FIG. 6, and FIG. 14 is a plan view of the thermal oxide film pattern 241 and mesh-like thermal oxide film pattern 252 shown in FIG. 13. FIG. 13 is a sectional view taken along the line A′-B′ in FIG. 14.

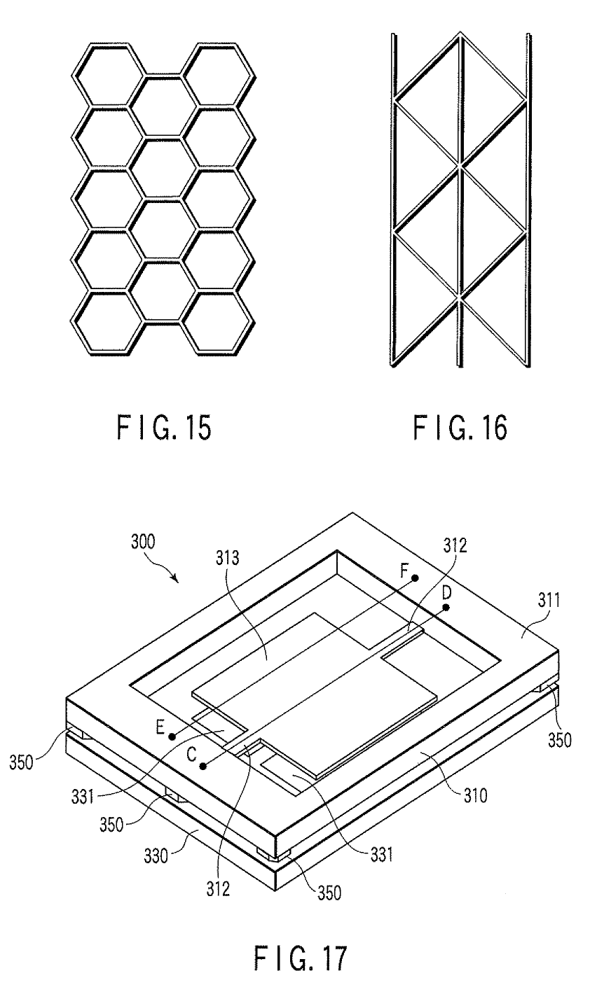

The added mesh-like oxide film pattern 252 eventually remains in the mirror support outer frame 111 as a finished product shown in FIGS. 1 and 2. As the total area of the pattern 252 is very small, the residual stress that may occur is very small and accordingly does not impair the effect of this embodiment. In FIG. 14, the mesh-like oxide film pattern 252 comprises a pattern formed by arranging straight lines like a grid. Alternatively, the oxide film pattern 252 may comprise a pattern formed by combining polygons other than squares, e.g., a honeycomb pattern or a pattern as a combination of triangles, as shown in FIGS. 15 and 16, or a pattern as a combination of curves.

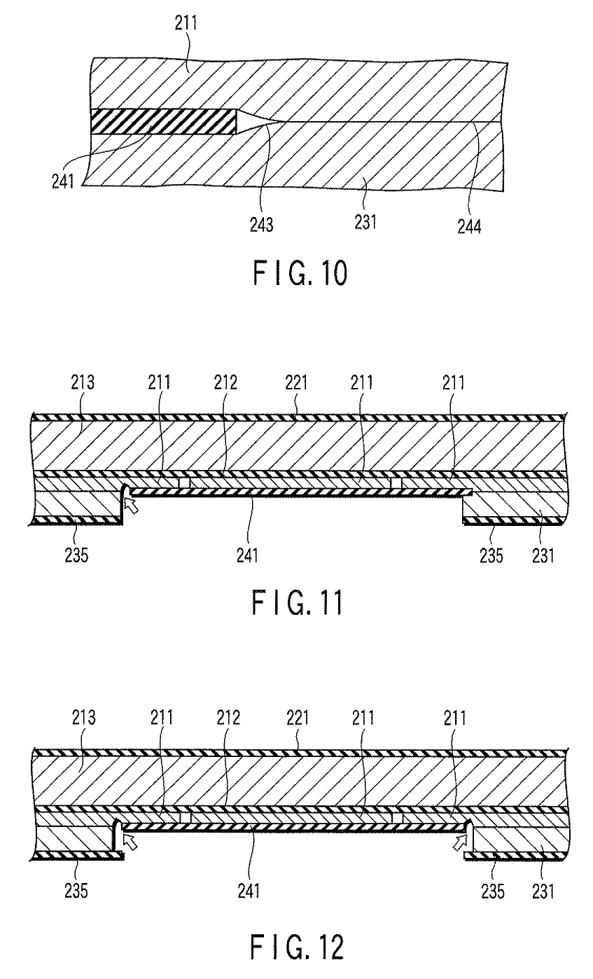

FIG. 10 shows in enlargement a near-end portion 242 of the thermal oxide film pattern 241 shown in FIG. 6. As shown in FIG. 10, in a region where the thermal oxide film pattern 241 does not exist, the active layer 211 and active layer 231 elastically deform and are accordingly bonded to each other through a bonding surface 244. Near the end of the thermal oxide film pattern 241, a step in the thermal oxide film pattern 241 forms a space 243. As the space 243 is very small, it does not degrade the bonding quality of the entire substrate.

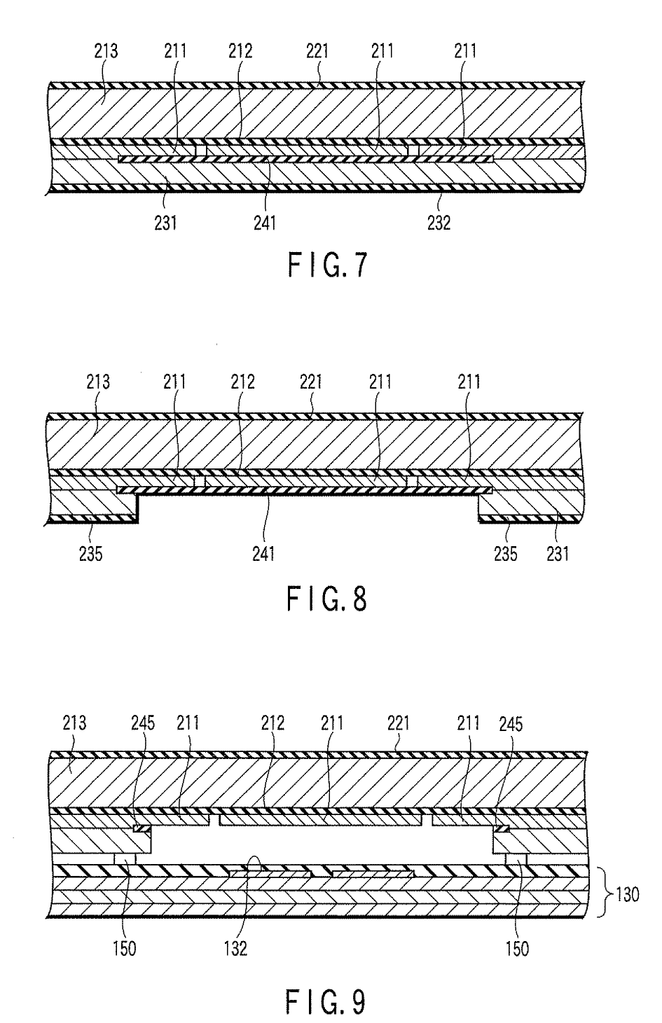

In FIG. 6, the support layer 233 is removed to obtain the structure shown in FIG. 7. As shown in FIG. 8, the exposed BOX layer 232 is patterned to form a second etching mask 235. Then, the portion of the active layer 231 that is not covered with the etching mask 235 is etched until the thermal oxide film pattern 241 is exposed. The thermal oxide film pattern 241 serves as an etching stop layer.

Suppose that the thermal oxide film pattern 241 has completely the same size as that of the active region. In this arrangement, for example, if the position of the second etching mask 235 is displaced by, e.g., an alignment error of the exposure apparatus, part of the active layer 211, that is, the portion indicated by an arrow in FIG. 11, is undesirably etched, as shown in FIG. 11. In etching the active layer 231, etching may progress not only in the direction of depth of the substrate but also along the surface of the substrate slightly. In this case, the same problem occurs. Namely, in the arrangement described above, the active layer 231 is etched in the direction along the substrate surface, as shown in FIG. 12, to undesirably etch part of the active layer 211, that is, the portion indicated by an arrow in FIG. 12.

To avoid this problem, as described with reference to FIG. 5, the thermal oxide film pattern 241 must be formed to be slightly larger than the active region by considering the performance of the apparatus to be used in the process, e.g., the alignment accuracy, etching finish shape, and the like.

Subsequently, the second etching mask 235 and the exposed portion of the thermal oxide film pattern 241 are removed, and the resultant structure is bonded to the MCM substrate 130 formed with the electrodes 132 and pads 150, as shown in FIG. 9. Finally, the thermal oxide film 221, support layer 213, and BOX layer 212 are removed to complete the tilt mirror element 100 shown in FIGS. 1 and 2.

In this embodiment, of the thermal oxide film pattern 241 formed as the etching stop layer of the active layer 231, those portions other than the active region and its near-by region which are unnecessary in the process are removed in advance. This decreases the area of the silicon oxide film remaining in the mirror substrate 110 of the completed tilt mirror element 100. As a result, the warp of the mirror substrate 110 is decreased, and a decrease in performance of the tilt mirror element 100 resulting from the warp is prevented.

This embodiment can be changed in various manners without departing from the spirit or scope of the present invention.

Although the moving element is exemplified by a tilt mirror element, the moving element is not limited to this, but may be any other MEMS element formed by the same process, e.g., an element in which an elastic body that supports a moving body does not torsionally deform but deforms by stretch and contraction, or an element in which a moving body does not deflect but moves directly. Although the two ends of the moving body are supported by the torsion springs in this embodiment, the supporting form of the moving body is not limited to this, but can be a so-called cantilever structure in which only one end of the moving body is supported by a spring. In this embodiment, as an etching stop layer, a silicon oxide film is formed in the substrate. A film made of any other material, e.g., a silicon nitride film, a resin film, or a metal film, may be formed in the substrate as far as it has resistance to etching of the substrate and can be removed without damaging the constituent elements of the element. In this case, the buried film is preferably formed so that a tensile stress remains in the direction to pull the active and support layers on its upper or lower surface. This prevents slack or wrinkles in the buried film when releasing the structure in the final step, avoiding fracture in a small structure such as a torsion spring.

### Second Embodiment

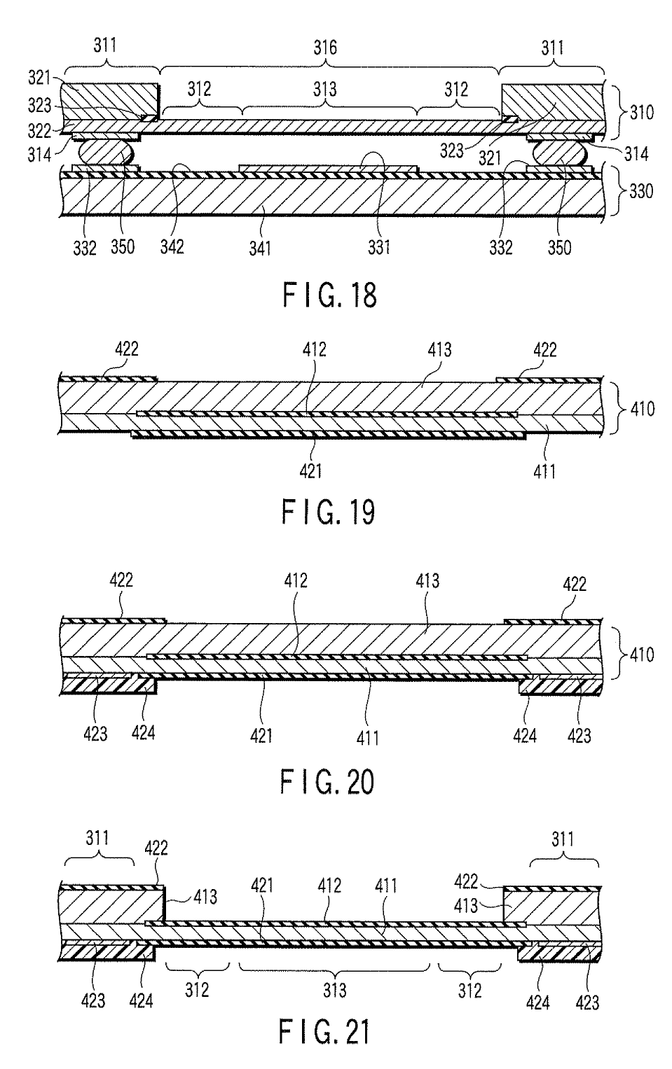

FIGS. 17 and 18 show a tilt mirror element as a moving element according to the second embodiment. The tilt mirror element 300 comprises a mirror substrate 310 and an electrode substrate 330. The mirror substrate 310 and electrode substrate 330 are bonded to each other through bumps 350. The mirror substrate 310 comprises a mirror support frame 311 serving as a support, two torsion springs 312 serving as elastic bodies, and a mirror plate 313 serving as a moving body. The mirror plate 313 is located inside the mirror support frame 311. The two torsion springs 312 connect the mirror plate 313 to the mirror support frame 311. The two torsion springs 312 are symmetrically arranged on a straight line extending through the center of the mirror plate 313. Bonding pads 314 are formed on the mirror support frame 311 and are electrically connected to the mirror plate 313 through the torsion springs 312.

The electrode substrate 330 has two electrodes 331 opposing the mirror plate 313. The two electrodes 331 are axi-symmetrically arranged with respect to a straight line extending through the torsion springs 312. The torsion springs 312 are torsionally deformable. Thus, the mirror plate 313 is allowed to tilt with respect to the mirror support frame 311. Bonding pads 332 are formed on the electrode substrate 330. The electrodes 331 and bonding pads 332 are formed on an insulating film 342 formed on a substrate 341 such as a silicon substrate. The electrodes 331 and bonding pads 332 are electrically connected to a control circuit (not shown) and a power supply (not shown) through wirings (not shown).

The mirror substrate 310 and electrode substrate 330 are fixed to each other by the bumps 350, which electrically connect the bonding pads 314 and bonding pads 332 to each other. The bumps 350 serve not only for electrically connecting the bonding pads to each other but also for arranging the mirror plate 313 away from the electrode substrate 330.

The tilt mirror element 300 operates almost in the same manner as the tilt mirror element 100 shown in FIGS. 1 and 2. While the mirror plate 313 is grounded, when applying a voltage to one of the two electrodes 331, an electrostatic attracting force is generated between the voltage-applied electrode 331 and the mirror plate 313. The voltage-applied electrode 331 attracts the mirror plate 313 to tilt the mirror plate 313 about an axis extending through the torsion springs 312.

As shown in FIG. 18, the torsion springs 312 and mirror plate 313 comprise a silicon layer 322, and the mirror support frame 311 comprises two silicon layers, i.e., the silicon layer 321 and a silicon layer 322, and a silicon oxide film 323. The silicon layers 321 and 322 are preferably made of single-crystal silicon. The silicon oxide film 323 to be used for substrate processing is buried in the mirror support frame 311. The silicon oxide film 323 is formed only near an opening 316 of the mirror support frame 311 and does not exist elsewhere. Namely, the silicon oxide film 323 as the buried film is formed only near end faces of the mirror support frame 311 that face the mirror plate 313. Accordingly, the area of the silicon oxide film buried in the mirror support frame 311 is very small, in the same manner as in the first embodiment. This largely decreases the warp of the mirror substrate 310.

A method of manufacturing the tilt mirror element shown in FIGS. 17 and 18 will be described with reference to FIGS. 19 to 25. FIGS. 19 to 24 show sections corresponding to that in FIG. 18, and FIG. 25 shows a section taken along the line E-F in FIG. 17. In this description, the portion that corresponds to the opening 316 of the mirror support frame 311 will be referred to as an active region.

First, as shown in FIG. 19, an SOI substrate 410 in which a patterned BOX layer 412 has been buried in advance is prepared. Thermal oxide films are respectively formed on the surfaces of the SOI substrate 410, and patterned by etching or the like to form etching masks 421 and 422. The etching mask 421 has a pattern corresponding to the shape of the torsion springs 312 and mirror plate 313, and the etching mask 422 has a shape corresponding to the shape of the mirror support frame 311. The BOX layer 412 is formed in only the active region and its vicinity. In the first embodiment, the thermal oxide film pattern 241 must be formed to be larger than the active region. For the same reason as that for this in the first embodiment, the size of the BOX layer 412 must be slightly larger than that of the active region considering the performance of an apparatus to be employed in the process. Of the surfaces of the SOI substrate 410, the surface where the etching mask 421 is formed will be referred to as an upper surface, and the surface where the etching mask 422 is formed will be referred to as a lower surface.

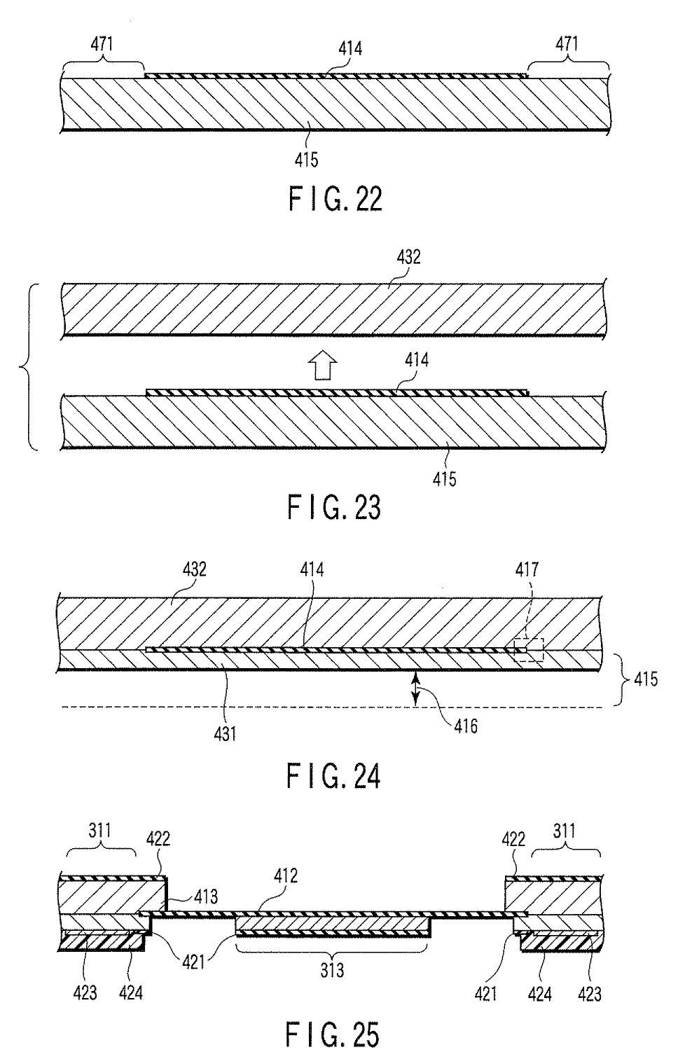

The SOI substrate 410 is a substrate formed by bonding two silicon substrates 411 and 413 through the patterned BOX layer 412, and is fabricated in, e.g., the following manner. First, as shown in FIG. 22, a silicon oxide film pattern 414 is formed on the surface of a silicon substrate 415. After that, as shown in FIG. 23, another silicon substrate 432 is bonded to the surface of the silicon substrate 415. Furthermore, as shown in FIG. 24, an unnecessary portion 416 of the silicon substrate 415 is removed by polishing, etching, or the like to form a silicon substrate 431. In this manner, an SOI substrate in which a patterned BOX layer is buried is finished. In FIG. 24, the silicon substrates 431 and 432 and the silicon oxide film pattern 414 respectively correspond to the silicon substrates 411 and 413 and the BOX layer 412 in FIG. 19. At a near-end portion 417 of the silicon oxide film pattern 414, where the silicon oxide film pattern 414 does not exist, the silicon substrates 431 and 432 that are bonded to each other elastically deform and are directly bonded to each other. The silicon oxide film pattern 414 is thus buried in the silicon substrates 431 and 432 to form a BOX layer, in the same manner as described in the first embodiment with reference to FIG. 10. An alignment mark to determine the planar position of the silicon oxide film pattern 414 in FIG. 22 is formed simultaneously with or in a step before or after the pattern forming step for the silicon oxide film pattern 414.

In FIG. 22, if a portion 471 where the silicon oxide film pattern 414 does not exist has a large area, in bonding the silicon substrate 432 to the silicon substrate 415 in FIG. 23, voids may be formed in the bonding interface oftener. To avoid this phenomenon, while a mesh-like oxide film pattern is formed on the portion 471 where the silicon oxide film pattern 414 does not exist, the silicon substrate 432 is bonded to the silicon substrate 415, in the same manner as in the scheme described in the first embodiment with reference to FIGS. 13 and 14.

Subsequently, as shown in FIG. 20, a conductive film such as an aluminum film is formed on the upper surface of the SOI substrate 410, and patterned by etching or the like to form bonding pads 423. The bonding pads 423 are formed to be in direct contact with the silicon substrate 411. To protect portions around the bonding pads 423, resist patterns 424 are formed in regions including the bonding pads 423.

Silicon of the portions of the SOI substrate 410 that are not covered with the etching masks 421 and 422 and resist patterns 424 is removed from the upper surface and lower surface by etching or the like until the BOX layer 412 is exposed completely. This forms a mirror plate 313, torsion springs 312, and a mirror support frame 311, as shown in FIG. 21. The BOX layer 412 serves as an etching stop layer. At this point, the sectional structure taken along the line E-F in FIG. 17 is as shown in FIG. 25.

Finally, the resist patterns 424 are removed. The etching masks 421 and 422 and the portions of the BOX layer 412 that are exposed to the outside are then removed. Then, the resultant structure is bonded to the electrode substrate 330 through the bumps 350, thus finishing the tilt mirror element shown in FIGS. 17 and 18. As the BOX layer 412 of the SOI substrate 410 is patterned in advance, the BOX layer 412 is mostly removed in this step. This prevents the mirror support frame 311 from warping.

In this embodiment, of the BOX layer buried in the SOI substrate, portions that are unnecessary in the process are removed in advance. This decreases the area of the silicon oxide film remaining in the mirror substrate of the completed tilt mirror element. As a result, the warp of the mirror substrate is decreased, and a decrease in performance of the tilt mirror element resulting from the warp is prevented.

This embodiment may be modified in various manners without departing from the spirit or scope of the present invention.

Although the moving element is exemplified by a tilt mirror element that deflects in only one axial direction, this embodiment may also be applied to an element that deflects in two axial directions, as shown in the first embodiment. The moving element is not limited to this, but may be any other MEMS element formed by etching an SOI substrate from the two surfaces, e.g., an element in which an elastic body that supports a moving body deforms by stretch and contraction, or an element in which a moving body moves directly. Although the two ends of the moving body are supported by the torsion springs in this embodiment, the supporting mode of the moving body is not limited to this, but may be a so-called cantilever structure in which only one end of the moving body is supported by a spring. In this embodiment, as an etching stop layer, a patterned silicon oxide film is formed in the substrate. A patterned film made of any other material, e.g., a silicon nitride film, a resin film, or a metal film, may be formed in the substrate as far as it has resistance to etching of the substrate and can be removed without damaging the constituent elements of the element. In this case, the buried film is preferably formed so that a tensile stress remains in the direction to pull the silicon substrate that has the buried film layer on its upper or lower surface. This prevents slack or wrinkles in the buried film when releasing the structure in the final step, avoiding fracture in a small structure such as a torsion spring.

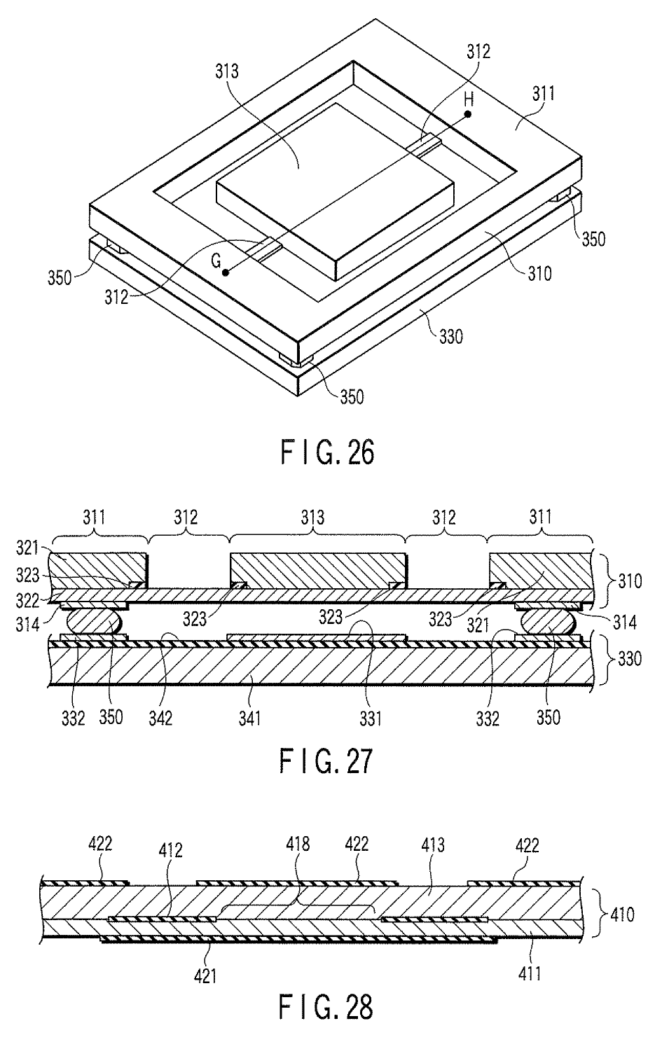

In this embodiment, the mirror plate 313 is formed to have the same thickness as that of each torsion spring 312. Alternatively, in the step in FIG. 19, an etching mask 422 is formed also at a portion that forms the mirror plate 313, as shown in FIG. 28, so the mirror plate 313 has the same thickness as that of the mirror support frame 311, as shown in FIGS. 26 and 27. In this case, preferably, the BOX layer 412 of the SOI substrate buried in the step in FIG. 19 is removed not only at a portion to be buried in the mirror support frame, excluding the portion near the end faces of the mirror support frame that face the mirror plate, but also at a portion 418 to be buried in the mirror plate, excluding the portion near the end faces of the mirror plate, as shown in FIG. 28. In the mirror substrate 310 to be formed as a consequence, the silicon oxide film 323 as a buried film is formed only near the end faces of the mirror plate 313 as a moving body and near the end faces of the mirror support frame 311 that face the mirror plate 313. This prevents not only the warp of the mirror support frame but also the warp of the mirror plate. Moreover, in this case, if the area of the portion 418 to be buried in the mirror plate, excluding the portion near the end faces of the mirror plate where the BOX layer 412 does not exist, is large, when burying the BOX layer 412 in the SOI substrate 410 by bonding, voids may be formed oftener. To avoid this phenomenon, while a mesh-like oxide film pattern is formed in the portion 418 to be buried in the mirror plate, excluding the portion near the end faces of the mirror plate where the BOX layer 412 does not exist, the two silicon substrates 411 and 413 may be bonded, in the same manner as in the scheme described in the first embodiment with reference to FIGS. 13 and 14.

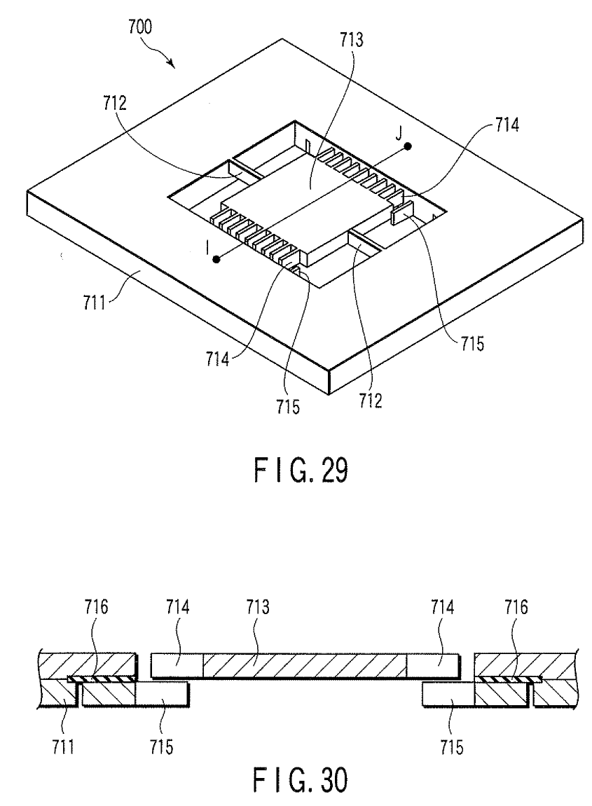

In this embodiment, the moving element comprises two substrates, i.e., a mirror substrate and an electrode substrate. Alternatively, the moving element may comprise one substrate, as shown in FIGS. 29 and 30. This moving element 700 comprises a mirror support frame 711, a mirror plate 713, torsion springs 712 connecting the mirror plate 713 to the mirror support frame 711, and a comb actuator to rotate the mirror plate 713. The comb actuator comprises comb structures 714 and 715 formed at positions separate from each other. The mirror plate 713 is rotated by the electrostatic attracting force that is generated between the comb structures 714 and 715 upon applying a voltage between them.

This structure is also formed by the steps shown in FIGS. 19 to 25. More specifically, a mask to form the torsion springs 712 and comb structures 714 may be reflected in the etching mask 421 in FIG. 19, and a mask to form the comb structures 715 may be reflected in the etching mask 422 in FIG. 19.

As shown in FIG. 30, a BOX layer 716 is formed only near the end faces of the mirror support frame 711 that face the mirror plate 713 and does not exist in the other region. Thus, the warp in the mirror support frame 711 is decreased greatly.

### Third Embodiment

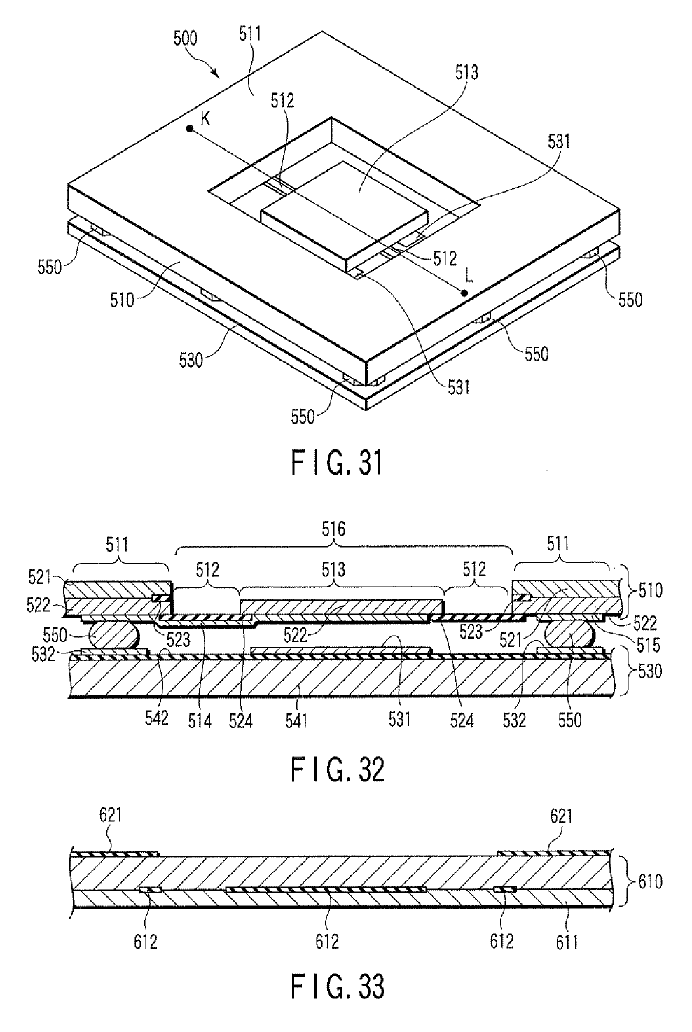

FIGS. 31 and 32 show a tilt mirror element as a moving element according to the third embodiment. The tilt mirror element 500 comprises a mirror substrate 510 and an electrode substrate 530. The mirror substrate 510 and electrode substrate 530 are bonded to each other through bumps 550. The mirror substrate 510 comprises a mirror support frame 511 serving as a support, torsion springs 512 serving as elastic bodies, and a mirror plate 513 serving as a moving body. The mirror plate 513 is located inside the mirror support frame 511. The two torsion springs 512 connect the mirror plate 513 to the mirror support frame 511. The torsion springs 512 are symmetrically arranged on a straight line extending through the center of the mirror plate 513. The torsion springs 512 comprise silicon nitride films. Wirings 514 are formed on the surfaces of the torsion springs 512 and electrically connect the mirror support frame 511 to the mirror plate 513. Bonding pads 515 are formed on the mirror support frame 511 and are electrically connected to the mirror plate 513 through the mirror support frame 511 and wirings 514.

The electrode substrate 530 has two electrodes 531 opposing the mirror plate 513. The two electrodes 531 are axi-symmetrically arranged with respect to a straight line extending through the torsion springs 512. The torsion springs 512 are torsionally deformable. Thus, the mirror plate 513 is allowed to tilt with respect to the mirror support frame 511. Bonding pads 532 are formed on the electrode substrate 530. The electrodes 531 and bonding pads 532 are formed on an insulating film 542 formed on a substrate 541 such as a silicon substrate. The electrodes 531 and bonding pads 532 are electrically connected to a control circuit (not shown) and a power supply (not shown) through wirings (not shown).

The mirror substrate 510 and electrode substrate 530 are fixed to each other by the bumps 550, which electrically connect the bonding pads 532 and bonding pads 515 to each other. The bumps 550 serve not only for electrically connecting the bonding pads to each other but also for arranging the mirror plate 513 away from the electrode substrate 530.

The tilt mirror element 500 operates in the same manner as the tilt mirror element 300 of the second embodiment. While the mirror plate 513 is grounded through the bonding pads 532, bumps 550, wirings 514, and bonding pads 515, a voltage is applied to one of the two electrodes 531 to generate an electrostatic attracting force between the mirror plate 513 and the voltage-applied electrode 531, which causes the mirror plate 513 to be rotated through a desired angle.

As shown in FIG. 32, the mirror plate 513 comprises a silicon layer 522, the torsion springs 512 comprise silicon nitride films, and the mirror support frame 511 comprises two silicon layers, i.e., a silicon layer 521 and the silicon layer 522, and a silicon oxide film 523. The silicon layers 521 and 522 are preferably made of single-crystal silicon. The silicon oxide film 523 to be used for substrate processing is buried in the mirror support frame 511. The silicon oxide film 523 is formed only near an opening 516 of the mirror support frame 511 and does not exist elsewhere. Namely, the silicon oxide film 523 as the buried film is formed only near end faces of the mirror support frame 511 that face the mirror plate 513. Accordingly, the area of the silicon oxide film 523 buried in the mirror support frame 511 is very small, in the same manner as in the first and second embodiments. This largely decreases the warp of the mirror substrate 510.

A method of manufacturing the tilt mirror element shown in FIGS. 31 and 32 will be described with reference to FIGS. 33 to 35. FIGS. 33 to 35 show sections corresponding to that in FIG. 32. In this description, the portion corresponding to the opening 516 of the mirror support frame 511 will be referred to as an active region.

First, as shown in FIG. 33, an SOI substrate 610 in which a patterned BOX layer 612 has been buried in advance is prepared. A thermal oxide film is formed on the surface of the SOI substrate 610, and patterned by etching or the like to form an etching mask 621. Note that the BOX layer 612 is formed only in the active region and its vicinity. In the first embodiment, the thermal oxide film pattern 241 must be formed to be larger than the active region. For the same reason as that for this in the first embodiment, the size of the BOX layer 612 must be slightly larger than the active region considering the performance of an apparatus to be used in the process. The etching mask 621 has a pattern corresponding to the shape of the mirror support frame 511 in FIG. 32, and the BOX layer 612 has a pattern corresponding to the shape of the mirror plate 513 in FIG. 32. Of the surfaces of the SOI substrate 610, the surface where the etching mask 621 is formed will be referred to as a lower surface, and the surface where nothing is formed will be referred to as an upper surface hereinafter.

The SOI substrate 610 used here is manufactured by, e.g., the method described in the second method with reference to FIGS. 22 to 24.

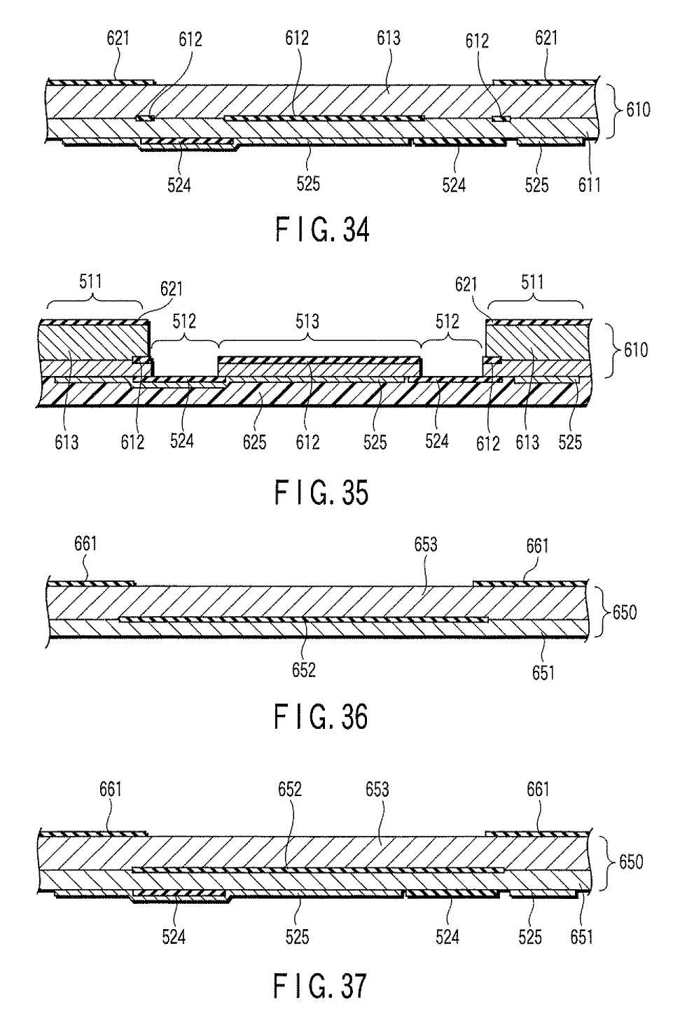

Subsequently, as shown in FIG. 34, a low-stress silicon nitride film is formed on the surface of the SOI substrate 610, and patterned by etching or the like to form a nitride film pattern 524 on the upper surface of the SOI substrate 610. The nitride film pattern 524 has a pattern corresponding to the shapes of the torsion springs 512 in FIG. 32. A conductive film such as an aluminum films is formed on the upper surface of the SOI substrate 610 and patterned by etching or the like to form a conductive film pattern 525. The conductive film pattern 525 has a pattern corresponding to the shapes of the wirings 514 and bonding pads 515 in FIG. 32.

Subsequently, as shown in FIG. 35, a protection film 625 comprising a polyimide resin or the like is formed on the upper surface of the SOI substrate 610. After that, silicon of only the portion of the SOT substrate 610 that is not covered with the etching mask 621 is removed from the lower surface by etching or the like until the BOX layer 612 is exposed. When the BOX layer 612 is exposed, silicon of only the portion of the SOI substrate 610 that is not covered with the BOX layer 612 is successively removed by etching or the like until the protection film 625 or nitride film pattern 524 is exposed. In this step, silicon of the portion that is covered with the etching mask 621 is not etched but remains to form the mirror support frame 511. Until the BOX layer 612 is exposed, silicon of the portion that is not covered with the etching mask 621 is entirely removed. Once the BOX layer 612 is exposed, silicon of the portion that is covered with the BOX layer 612 is not removed but remains to form the mirror plate 513. The protection film 625 and nitride film pattern 524 serve as etching stop layers.

Finally, the portion of the BOX layer 612 that is exposed to the outside, the etching mask 621, and the protection film 625 are removed. The resultant structure is bonded to the electrode substrate 530 through the bumps 550 to finish the tilt mirror element 500 shown in FIGS. 31 and 32. In the SOI substrate 610, the BOX layer 612 is patterned in advance and removed except for at the active region and its nearby region. Thus, in this step, most portions of the BOX layer 612 are removed. This prevents the warp of the mirror support frame 511.

Another method of manufacturing the tilt mirror element shown in FIGS. 31 and 32 will be described with reference to FIGS. 36 to 39. FIGS. 36 to 39 show sections corresponding to that in FIG. 32.

First, as shown in FIG. 36, an SOI substrate 650 in which a patterned BOX layer 652 has been buried in advance is prepared. A thermal oxide film is formed on the surface of the SOI substrate 650, and patterned by etching or the like to form an etching mask 661. The etching mask 661 has a pattern corresponding to the shape of the mirror support frame 511. Of the surfaces of the SOI substrate 650, the surface where the etching mask 661 is formed will be referred to as a lower surface, and the surface where nothing is formed will be referred to as an upper surface hereinafter.

Subsequently, as shown in FIG. 37, a nitride film pattern 524 comprising a low-stress silicon nitride film or the like and a conductive film pattern 525 made of aluminum or the like are formed on the upper surface of the SOI substrate 650. The nitride film pattern 524 has a pattern corresponding to the shapes of the torsion springs 512. The conductive film pattern 525 has a pattern corresponding to the shapes of the wirings 514 and bonding pads 515.

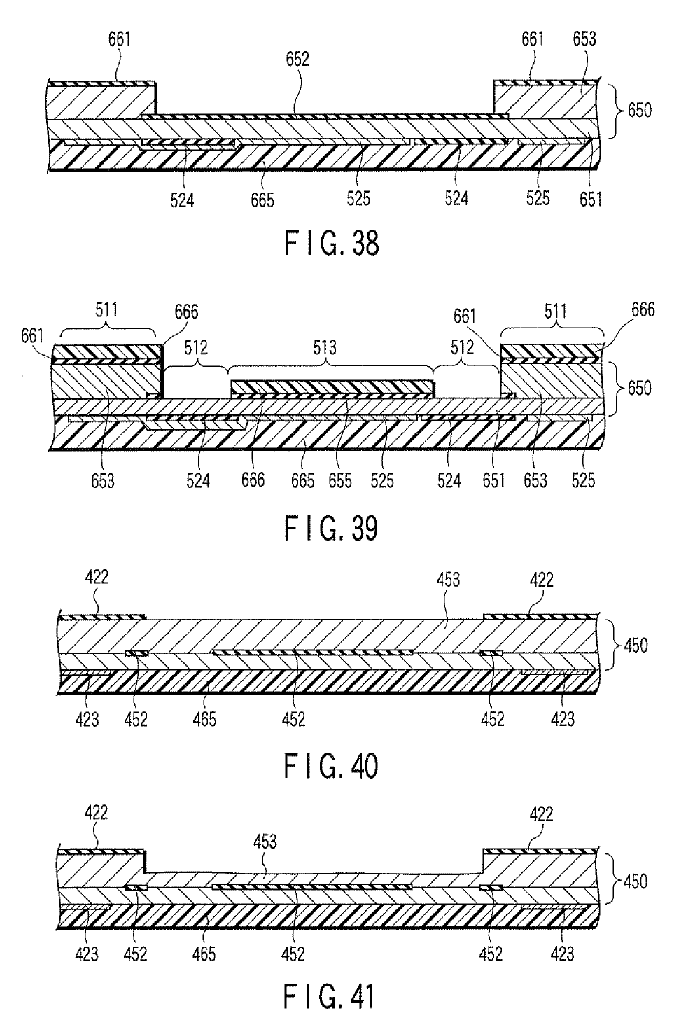

Subsequently, as shown in FIG. 38, a protection film 665 comprising a polyimide resin or the like is formed. Then, silicon of the portion of the SOI substrate 650 that is not covered with the etching mask 661 is etched from the lower surface until the BOX layer 652 is exposed. Furthermore, as shown in FIG. 39, a resist pattern 666 formed. The portion of the exposed portion of the BOX layer 652 that is not covered with the resist pattern 666 is removed to form an etching mask 655. The etching mask 655 has a pattern corresponding to the shape of the mirror plate 513.

Subsequently, the resist pattern 666 is removed, and silicon of only the portion of the SOI substrate 650 that is not covered with the etching mask 655 is etched from the lower surface to form a structure identical to that shown in FIG. 35.

Finally, the etching mask 655, etching mask 661, and protection film 665 are removed, and the resultant structure is bonded to the electrode substrate 530 through bumps to complete the tilt mirror element 500 shown in FIGS. 31 and 32.

In this embodiment, of the BOX layer buried in the SOI substrate, those portions which are unnecessary in the process are removed in advance. This decreases the area of the silicon oxide film remaining in the mirror substrate of the completed tilt mirror element. As a result, the warp of the mirror substrate is decreased, and a decrease in performance of the tilt mirror element resulting from the warp is prevented.

After the step in FIG. 35, the process is performed while the upper surface of the substrate is protected by the protection film 625 or 665. This prevents fracture of the torsion springs or the like during the process, leading to an expectation for a higher yield.

This embodiment may be modified in various manners without departing from the spirit or scope of the present invention.

Although the moving element is exemplified by a tilt mirror element that deflects in only one axial direction, this embodiment may also be applied to an element that deflects in two axial directions, as shown in the first embodiment. The moving element is not limited to this, but may be any other MEMS element formed by etching an SOI substrate from one surface, e.g., an element in which an elastic body that supports a moving body is deformed by stretch and contraction, or an element in which a moving body moves directly. Although the two ends of the moving body are supported by the torsion springs in this embodiment, the supporting mode of the moving body is not limited to this, but may be a so-called cantilever structure in which only one end of the moving body is supported by a spring.

In this embodiment, an SOI substrate, i.e., a substrate in which a silicon oxide film is buried is used. Alternatively, a substrate in which another material, e.g., a silicon nitride film, a resin film, or a metal film, is buried may be used as far as it is made of a material that has a resistance against etching of the substrate and can be removed without damaging the constituent elements of the element.

A polyimide resin film formed as a protection film on the upper surface of the substrate is used as an etching stop layer. Alternatively, a film made of another material, e.g., a silicon nitride film, a resin film, or a metal film, may be used as an etching stop layer as far as it has a resistance to etching of the substrate and can be removed without damaging the constituent elements of the element. In this case, the protection film is preferably formed so that a tensile stress remains in the direction to pull the underlying silicon substrate. This prevents slack or wrinkles in the protection film when releasing the structure in the final step, avoiding fracture in a small structure such as a torsion spring.

In this embodiment, a low-stress silicon nitride film is used as the material of the torsion springs. Alternatively, another inorganic insulating film, a resin film such as a polyimide film, or a conductive film such as a titanium film may be used instead. When using a conductive film as the material of the torsion springs, in the step in FIG. 34, the nitride film pattern 524 is not used, but part of the conductive film pattern 525 is used as the torsion springs. In this embodiment, the mirror plate 513 is formed to have a thickness different from that of the mirror support frame 511. Alternatively, in the step shown in FIG. 33, if the etching mask 621 is formed to cover also the prospective mirror plate portion, the mirror plate 513 in FIG. 32 may be formed to have the same thickness as that of the mirror support frame 511. In this case, the BOX layer 612 of the SOI substrate 610 buried in FIG. 33 is removed not only at a portion to be buried in the mirror support frame, excluding the portion near the end faces of the mirror support frame that face the mirror plate, but also at the portion to be buried in the mirror plate excluding the portion near the end faces of the mirror plate. This prevents the warp of the mirror plate as well.

According to the second embodiment, in the steps in FIGS. 21 and 25, part of the SOI substrate 410 is etched from the upper surface by using the etching mask 421 to form the torsion springs 312. Alternatively, by adopting the third embodiment, the torsion springs 312 may be formed by etching the SOI substrate 410 from the lower surface.

More specifically, as shown in FIG. 40, a BOX is layer 452 of an SOI substrate 450 is formed to have the same shape as that of the etching mask 421. The etching mask 422 is formed on the lower surface of the SOI substrate 450 in accordance with the scheme described above. After forming the bonding pads 423 on the upper surface of the SOI substrate 450 in accordance with the scheme described above, an etching stop layer 465 comprising a polyimide resin or the like is formed on the entire upper surface of the SOI substrate 450. FIG. 40 shows a section taken along the line E-F in FIG. 17.

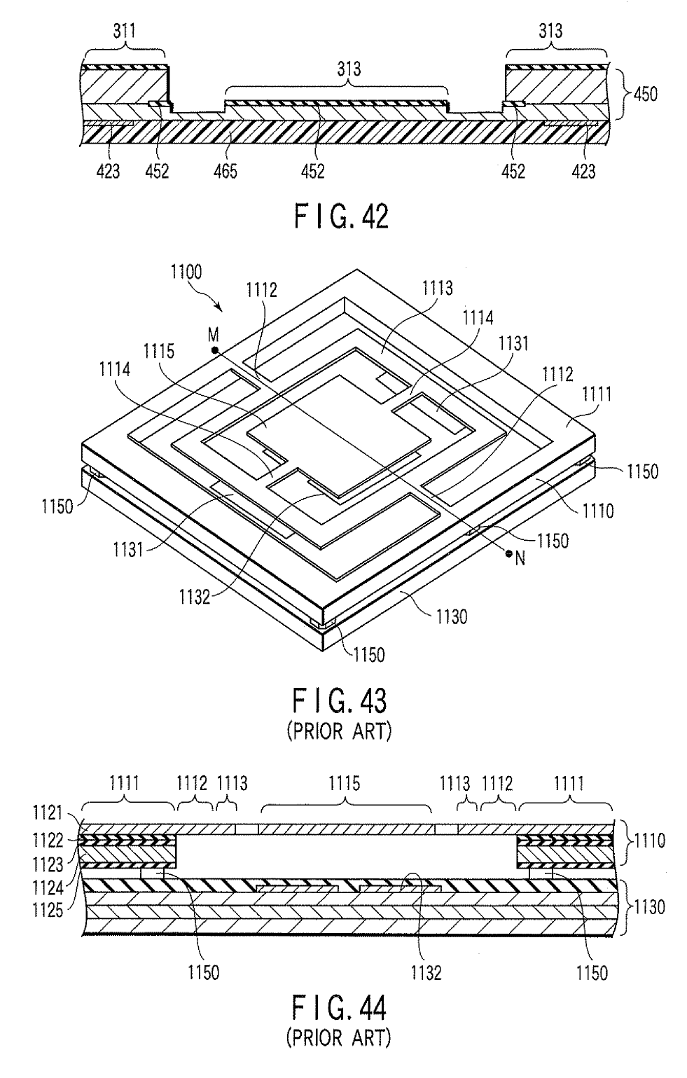

When etching the structure shown in FIG. 40 from the lower surface, until the BOX layer 452 is exposed, all the portions that are not covered with the etching mask 422 are removed, as shown in FIG. 41. When etching progresses and the BOX layer 452 is exposed, the portion covered with the BOX layer 452 is not removed but remains, as shown in FIG. 42. When the substrate is further etched until the etching stop layer 465 is completely exposed, the mirror plate 313 and torsion springs (not shown) are formed.

Although the embodiments of the present invention have been described with reference to the accompanying drawing, the present invention is not limited to these embodiments, but various changes and modifications may be made within the spirit or scope of the gist of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A moving element comprising at least a substrate including a support, a moving body, and an elastic body connecting the moving body to the support, the support including a buried film formed therein, and the buried film of the support being formed only near end faces of the support that face the moving body.

2. An element according to claim 1, wherein the support includes a mesh-like pattern formed therein, the mesh-like pattern comprising the same material as that of the buried film.

3. An element according to claim 1, wherein the moving body includes a buried film formed therein, the buried film of the moving body being formed only near end faces of the moving body.

4. An element according to claim 2, wherein the moving body includes a buried film formed therein, the buried film of the moving body being formed only near end faces of the moving body.

5. An element according to claim 1, wherein the buried film comprises one of silicon oxide and silicon nitride.

6. An element according to claim 2, wherein the buried film comprises one of silicon oxide and silicon nitride.

7. An element according to claim 3, wherein the buried film of the support and the buried film of the moving body comprise one of silicon oxide and silicon nitride.

8. An element according to claim 4, wherein the buried film of the support and the buried film of the moving body comprise one of silicon oxide and silicon nitride.

9. A method of manufacturing a moving element according to claim 1, comprising steps of:
preparing an SOI substrate in which a patterned buried film is buried;
forming a first etching mask on a first surface of the substrate and forming a second etching mask on a second surface located on a rear side of the first surface;
etching, from the first surface, only a portion of the substrate that is not covered with the first etching mask until the buried film is exposed;
etching, from the second surface, only a portion of the substrate that is not covered with the second etching mask until the buried film is exposed; and
removing a portion of the buried film that is exposed to an outside.

10. A method of manufacturing a moving element according to claim 1, comprising steps of:
preparing an SOI substrate in which a patterned buried film is buried;
forming a first etching mask on a first surface of the substrate and forming an etching stop film on a second surface located on a rear side of the first surface;
etching, from the first surface, only a portion of the substrate that is not covered with the first etching mask until the buried film is exposed;
removing part of an exposed portion of the buried film to form a second etching mask; and
etching, from the first surface, only a portion of the substrate that is not covered with the second etching mask until the etching stop film is exposed.

11. A method of manufacturing a moving element according to claim 1, comprising steps of:
preparing an SOI substrate in which a patterned buried film is buried;
forming an etching mask on a first surface of the substrate and forming an etching stop film on a second surface located on a rear side of the first surface;
etching, from the first surface, only a portion of the substrate that is not covered with the etching mask until the buried film is exposed; and
subsequently, etching only a portion of the substrate that is not covered with the buried film until the etching stop film is exposed.
